(19) United States
(12) Patent Application Publication
(10) Pub. No.: US 2016/0062435 A1
(43) Pub. Date: Mar. 3, 2016

(54) MEMORY SYSTEM

(71) Applicant: KABUSHIKI KAISHA TOSHIBA, Tokyo (JP)

(72) Inventors: Nobuyuki ARAKAWA, Oume Tokyo (JP); Isao SAKAI, Yokohama Kanagawa (JP); Tomoki TANAKA, Yokohama Kanagawa (JP)

(21) Appl. No.: 14/637,279

(22) Filed: Mar. 3, 2015

(30) Foreign Application Priority Data
Sep. 2, 2014 (JP) 2014-178480

(51) Int. Cl. G06F 1/28; G06F 12/02; G06F 11/10; G11C 16/30

(52) U.S. Cl. CPC G06F 1/28; G11C 16/30; G06F 12/0238; G06F 11/1008; G06F 2212/222

(57) ABSTRACT

A memory system includes a nonvolatile memory, a thermoelectric device configured to generate power from heat, a main power supply for the nonvolatile memory, a backup power supply for the nonvolatile memory, the backup power supply including a capacitor, and a power supply controller configured to supply the power generated by the thermoelectric device to the capacitor to charge the capacitor.

### CROSS-REFERENCE TO RELATED APPLICATION

This application is based upon and claims the benefit of priority from Japanese Patent Application No. 2014-178480, filed Sep. 2, 2014, the entire contents of which are incorporated herein by reference.

### FIELD

Embodiments described herein relate generally to a memory system.

### BACKGROUND

As a type of nonvolatile semiconductor memory device, a NAND type flash memory is known. Furthermore, a storage device (for example, SSD) equipped with the NAND type flash memory is known.

### DESCRIPTION OF THE DRAWINGS

FIG. 1 is a block diagram illustrating a memory system according to a first embodiment.

FIG. 2 is a diagram schematically illustrating a cross section structure of the memory system.

FIG. 3 is a flowchart illustrating an operation of the memory system according to the first embodiment.

FIG. 4 is a graph illustrating an example of an internal temperature of the memory system.

FIG. 5 is a graph illustrating an example of power generated by a thermoelectric device.

FIG. 6 is a flowchart illustrating an operation of a memory system according to a modified example.

FIG. 7 is a block diagram illustrating a memory system according to a second embodiment.

FIG. 8 is a flowchart illustrating a write operation of the memory system according to the second embodiment.

FIG. 9 is a flowchart illustrating a read operation of the memory system according to the second embodiment.

FIG. 10 is a flowchart illustrating the read operation of the memory system subsequent to FIG. 9.

FIG. 11 is a flowchart illustrating a write operation of a memory system according to another example.

FIG. 12 is a flowchart illustrating the write operation of the memory system subsequent to FIG. 11.

### DETAILED DESCRIPTION

The present disclosure now will be described more fully hereinafter with reference to the accompanying drawings, in which various example embodiments are shown. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular example embodiments only and is not intended to limit the scope of the invention. As used herein, the singular forms “a,” “an” and “the” are intended to include the plurality of forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, may therefore, encompasses both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” may, therefore, encompass both an orientation of above and below.

Embodiments are described herein with reference to cross section and perspective illustrations that are schematic illustrations of idealized embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

Exemplary embodiments provide a high-quality memory system.

In general, according to one embodiment, a memory system includes a nonvolatile memory, a thermoelectric device configured to generate power from heat, a main power supply for the nonvolatile memory, a backup power supply for the nonvolatile memory, the backup power supply including a capacitor, and a power supply controller configured to supply the power generated by the thermoelectric device to the capacitor to charge the capacitor.

According to another embodiment, a method of managing power in a memory system that includes a nonvolatile memory, a thermoelectric device, a main power supply for the nonvolatile memory, and a backup power supply, including a capacitor, for the nonvolatile memory, includes the steps of generating power from heat using the thermoelectric device, and supplying the power generated by the thermoelectric device to the capacitor to charge the capacitor.

Hereinafter, embodiments will be described with reference to the drawings. However, the drawings are schematic and conceptual, and dimensions, proportions, and the like of each drawing are not necessarily the same as the actual ones. Some embodiments to be described below illustrates a device and a method for embodying the technical concept of an exemplary embodiment and a technical idea of an exemplary embodiment is not specified by a shape, a structure, an arrangement, and the like of configuration components.

Moreover, in the following description, the same reference numerals are given to elements having the same function and configuration, and duplicate description will be made only when necessary.

### First Embodiment

A memory system includes a nonvolatile semiconductor memory device (nonvolatile memory). In the embodiment, as the nonvolatile semiconductor memory device, a NAND type flash memory is described as an example. Furthermore, as the memory system, a Solid State Drive (SSD) that is a storage device including the NAND type flash memory is described as an example.

[1] Configuration of Memory System

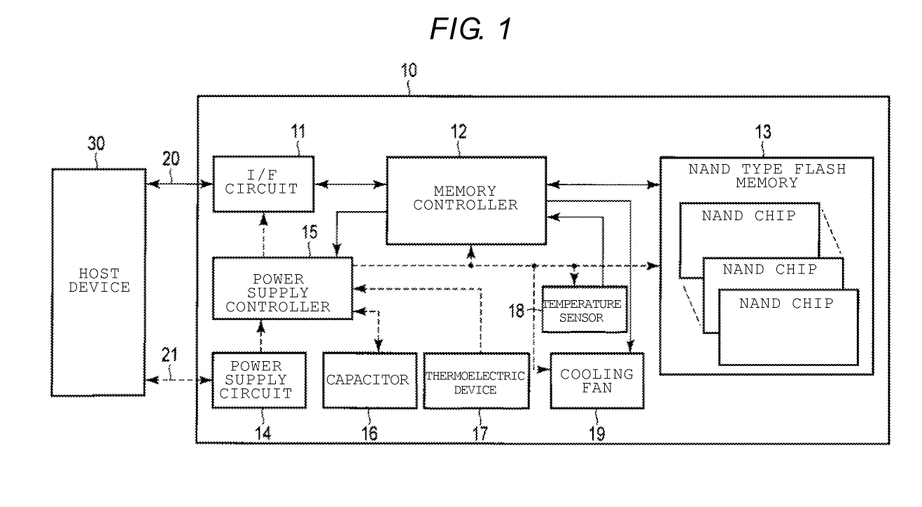

FIG. 1 is a block diagram illustrating a memory system 10 according to a first embodiment. The memory system 10 includes an interface circuit (I/F circuit) 11, a memory controller (SSD controller) 12, a NAND type flash memory 13, a power supply circuit 14, a power supply controller 15, a capacitor 16, a thermoelectric device 17, a temperature sensor 18, and a cooling fan 19. Moreover, in FIG. 1, a signal line is indicated by a solid line and a power line is indicated by a broken line to facilitate understanding of the drawings.

The interface circuit 11 is connected to a host device 30 through a signal line (bus) 20. The interface circuit 11 is a memory connection interface such as an Advanced Technology Attachment (ATA) interface and performs interface processing with the host device 30. The host device 30 is an external device that issues commands to write data to the memory system 10, read data from the memory system 10, and perform erasing of data written to the memory system 10, and, for example, is a personal computer, a server connected over a network, and the like.

The memory controller 12 includes a Central Processing Unit (CPU), a Random Access Memory (RAM), and the like. The memory controller 12 controls the entire operation of the memory system 10. The memory controller 12 has a function for processing a command with the host device 30, performing data transmission between the NAND type flash memory 13 and the host device 30, or managing each block in the NAND type flash memory 13.

The NAND type flash memory 13 is a nonvolatile semiconductor memory capable of storing data in nonvolatile and stores user data, programs, management data of the memory system 10, and the like. In the NAND type flash memory 13, erasing is performed in units of a block and writing and reading are performed in units of a page. The NAND type flash memory 13 includes a memory cell array in which a plurality of memory cells is disposed in a matrix configuration and the memory cell array includes a plurality of physical blocks. In the NAND type flash memory 13, writing of the data and reading of the data are performed for each physical page. The physical page includes a plurality of memory cells. The physical block includes a plurality of physical pages. For example, the NAND type flash memory 13 includes a plurality of NAND chips. The plurality of NAND chips may be individually controlled and may be operated in parallel.

The power supply circuit 14 is connected to the host device 30 through a power supply line 21 and receives a plurality of types of power from the host device 30. The power supply circuit 14 generates a plurality of types of power required within the memory system 10 using power supplied from the host device 30.

The power supply controller 15 receives power generated by the power supply circuit 14. The power supply controller 15 controls all of the power supplied inside the memory system 10. A specific operation of the power supply controller 15 will be described below.

The capacitor 16 functions as a battery and is a backup power supply of the memory system 10. For example, if a decrease in a power supply voltage, instantaneous interruption of the power supply voltage, abnormal power off of the memory system 10, and the like occur during operation of the memory system 10, the capacitor 16 supplies power to the power supply controller 15.

The thermoelectric device 17 has a function for converting thermal energy into electrical energy. As an example of the thermoelectric device 17, a device that generates electricity using a temperature difference between a heat source and portions other than the heat source, that is, a device using a Seebeck effect, maybe used. For example, a configuration of the thermoelectric device 17 is described in “THERMOELECTRIC DEVICE AND THERMOELECTRIIC MODULE”, U.S. patent application Ser. No. 12/964,152, filed on Dec. 9, 2010. This patent application is incorporated by reference herein in its entirety.

The temperature sensor 18 measures a temperature inside of the memory system 10. The cooling fan 19 cools the inside of the memory system 10 by supplying air to the inside of the memory system 10.

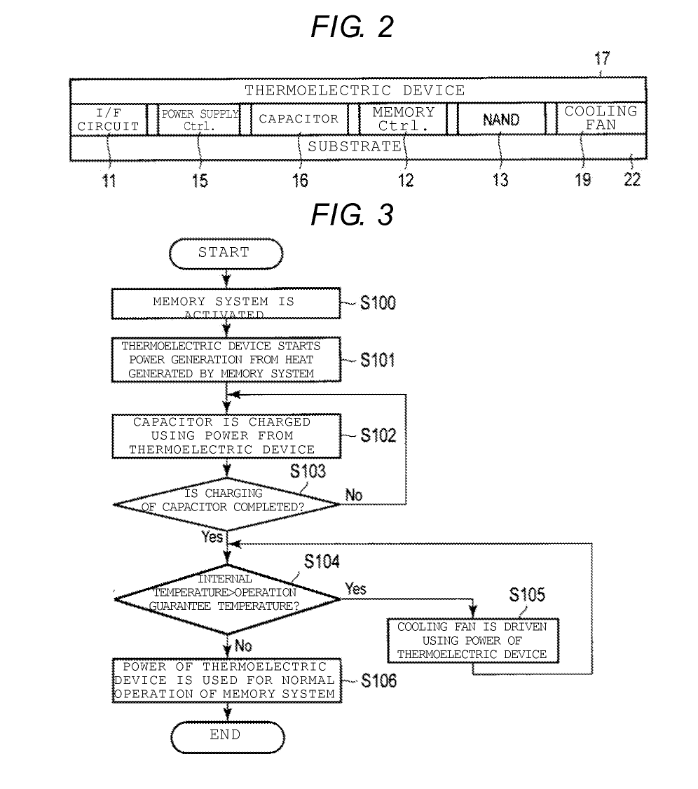

FIG. 2 is a diagram schematically illustrating a cross section structure of the memory system 10. A plurality of modules configuring the memory system 10 are mounted on a substrate 22. Moreover, as shown in FIG. 2, the modules mounted on the substrate 22 include the interface circuit 11, the memory controller 12, the NAND type flash memory 13, the power supply controller 15, the capacitor 16, and the cooling fan 19.

The thermoelectric device 17 is provided so as to be in contact with an entirety or a part of the modules. At least one surface of the thermoelectric device 17 that comes into contact with the modules is covered by an insulation film. In one embodiment, the thermoelectric device 17 is arranged so as to come into contact with only the modules that generate large amounts of heat (for example, the memory controller 12 and the like).

[2] Operation

An operation of the memory system 10 configured as described above will be described. FIG. 3 is a flowchart illustrating an operation of the memory system 10.

First, the power supply is supplied from the host device 30 to the memory system 10 through the power supply line 21 and thereby the memory system 10 is activated (step S100). Specifically, the power supply controller 15 receives power from the power supply circuit 14 and supplies the power to the interface circuit 11, the memory controller 12, the NAND type flash memory 13, and the temperature sensor 18. Thereafter, the memory system 10 performs a normal operation (including write operation, read operation, and erasing operation) in response to commands from the host device 30.

Subsequently, the entire memory system 10 (all modules inside the memory system 10) starts heat generation and thereby the thermoelectric device 17 starts power generation using the heat generated by the memory system 10 (step S101).

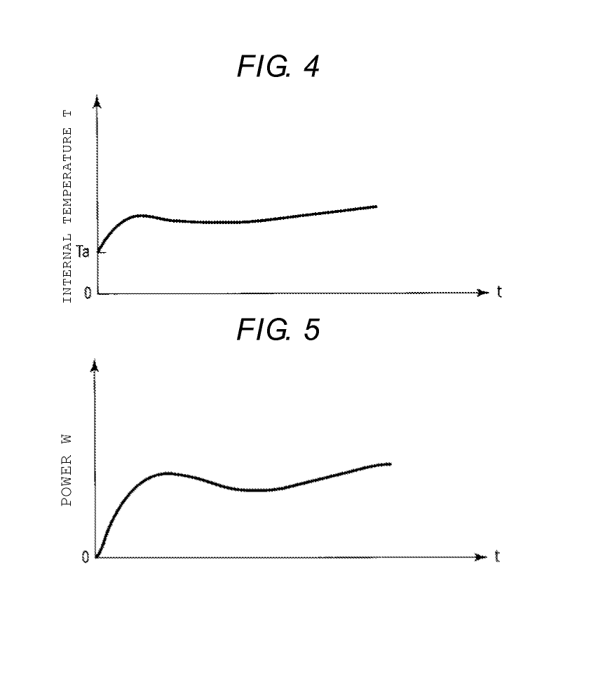

FIG. 4 is a graph illustrating an example of an internal temperature of the memory system 10. FIG. 5 is a graph illustrating an example of power generated by the thermoelectric device 17. A vertical axis of FIG. 4 is an internal temperature T of the memory system 10 and a horizontal axis is time t. A vertical axis of FIG. 5 is power W generated by the thermoelectric device 17 and a horizontal axis is time t.

When the internal temperature of the memory system 10 is a threshold Ta or more, the thermoelectric device 17 generates power using the heat of the memory system 10. When the internal temperature of the memory system 10 is less than a threshold Ta, the thermoelectric device 17 does not generate power. The threshold Ta is a value determined by a material and characteristics of the thermoelectric device 17.

Subsequently, the power supply controller 15 charges the capacitor 16 using power from the thermoelectric device 17 (step S102). Subsequently, the memory controller 12 determines whether or not the charging of the capacitor 16 is completed (step S103). The determination whether or not the charging of the capacitor 16 is completed may be performed by managing a charging time calculated based on the characteristics of the capacitor 16 and the thermoelectric device 17. That is, the memory controller 12 determines that the charging of the capacitor 16 is completed if an elapsed time from starting of the charging of the capacitor 16 exceeds the charging time calculated in advance.

In step S103, when the charging of the capacitor 16 is completed, the memory controller 12 monitors whether or not the internal temperature of the memory system 10 exceeds an operation guarantee temperature of the memory system 10 (step S104). The operation guarantee temperature is set depending on the specification of the memory system 10. The operation guarantee temperature referred herein is an operation guarantee temperature of the upper limit side (e.g., a maximum operating temperature) and, for example, approximately 70° C. to 85° C.

In step S104, if the internal temperature of the memory system 10 exceeds the operation guarantee temperature, the power supply controller 15 drives the cooling fan 19 using power from the thermoelectric device 17 (step S105). Meanwhile, if the internal temperature of the memory system 10 does not exceed the operation guarantee temperature, the power supply controller 15 uses power from the thermoelectric device 17 for the normal operation of the memory system 10 (step S106).

### MODIFIED EXAMPLE

The capacitor 16 may be a super capacitor. The super capacitor 16 is used to ensure the operation of the memory system 10 if abnormal power supply interruption occurs. A capacitance of the super capacitor 16 is set to be a capacitance or more that is necessary for supplying power in sufficient amounts to complete an operation that is carried out when the power supply of the memory system 10 is normally turned off, if abnormal power supply interruption occurs.

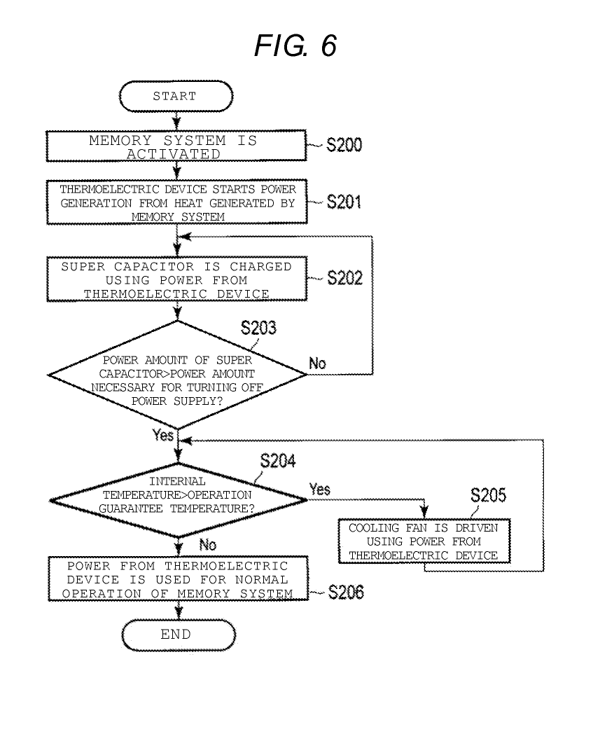

FIG. 6 is a flowchart illustrating an operation of a memory system 10 according to a modified example. Steps S200 and S201 of FIG. 6 are the same as steps S100 and S101 of FIG. 3.

Subsequently, the power supply controller 15 charges the super capacitor 16 using power from a thermoelectric device (step S202). Subsequently, a memory controller 12 determines whether or not a power amount accumulated in the super capacitor 16 exceeds a power amount necessary for the operation that is carried out when the power supply of the memory system 10 is normally turned off (step S203). The determination of the power amount accumulated in the super capacitor 16 may be managed by the charging time calculated in advance based on characteristics of the super capacitor 16 and the thermoelectric device 17.

In step S203, if the power amount of the super capacitor 16 exceeds the power amount necessary for the operation that is carried out when the power supply is normally turned off, the memory controller 12 monitors whether or not the internal temperature of the memory system 10 exceeds an operation guarantee temperature of the memory system 10 (step S204). Operations thereafter (steps S205 and S206) are the same as steps S105 and S106 of FIG. 3.

[3] Effects

As described above, in the first embodiment, the memory system 10 includes the thermoelectric device 17 generating power using the heat. Then, the power supply controller 15 performs the charging of the capacitor 16, the driving of the cooling fan 19, and the normal operation of the NAND type flash memory 13 using power generated by the thermoelectric device 17.

Thus, according to the first embodiment, it is possible to reduce the power consumption of the memory system 10. That is, it is possible to reduce the power consumption by the power amount generated by the thermoelectric device 17 in the power amount used in the memory system 10. Furthermore, the cooling fan 19 is driven using the power generated by the thermoelectric device 17 and it is possible to reduce the heat generation of the memory system 10.

In recent years, in order to meet a speed required level by a user, the SSD operates a plurality of NAND chips in parallel . Thus, heat generation by the SSD (specifically, memory controller) is increased and it is difficult to secure the operation guarantee temperature during the maximum load operation (for example, during sequential write operation). Furthermore, the power consumption is increased by the operation of the plurality of NAND chips in parallel.

In contrast, in the embodiment, since the power consumption of the memory system 10 may be reduced by the thermoelectric device 17, it is possible to program high speed operation of the memory system 10. Furthermore, since the heat generation of the memory system 10 may be reduced, it is possible to maintain the high speed operation of the memory system 10.

### Second Embodiment

[1] Configuration of Memory System

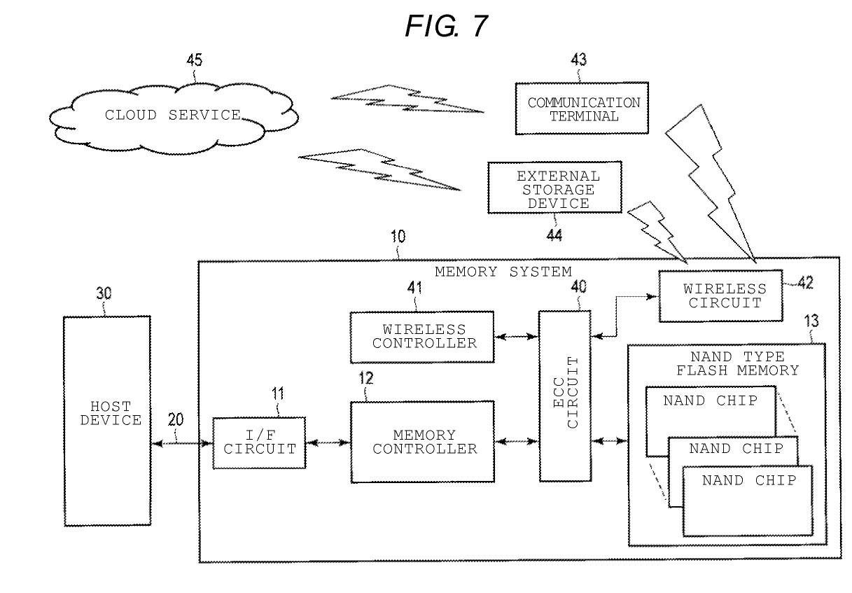

FIG. 7 is a block diagram of a memory system 10 according to a second embodiment. A memory system 10 includes an interface circuit 11, a memory controller 12, a NAND type flash memory 13, an Error Checking and Correcting (ECC) circuit 40, a wireless controller 41, and a wireless circuit 42.

The ECC circuit 40 generates an error correction code using write data when writing data. The error correction code is written in the NAND type flash memory 13 together with the write data. Furthermore, the ECC circuit 40 corrects an error of read data using the error correction code included in the read data when reading the data. The error correction code is removed from the read data.

The wireless circuit 42 performs wireless communication with an external device (including a communication terminal 43 and an external storage device 44). The wireless circuit 42 includes an antenna, a transmitting circuit, and a receiving circuit. The wireless communication may be carried out by wireless LAN complying with the IEEE802.11 Standard, Bluetooth (registered trademark), infrared communication, and the like. For example, the wireless circuit 42 receives a wireless signal from the communication terminal 43 and the external storage device 44 through the wireless LAN, and transmits the wireless signal to the communication terminal 43 and the external storage device 44.

The communication terminal 43 may be a cellular phone, a smart phone, or the like. The external storage device 44 maybe a Network Attached Storage (NAS) connected to the network, a server, or the like. For example, the communication terminal 43 and the external storage device 44 are connected to a cloud service 45 through the Internet and data or software is supplied from the cloud service 45.

The wireless controller 41 collectively controls the wireless communication. That is, the wireless controller 41 writes the data to the communication terminal 43 and the external storage device 44 through the wireless circuit 42 and reads the data from the communication terminal 43 and the external storage device 44.

[2] Operation

Next, an operation of the memory system 10 configured as described above, will be described.

Write Operation

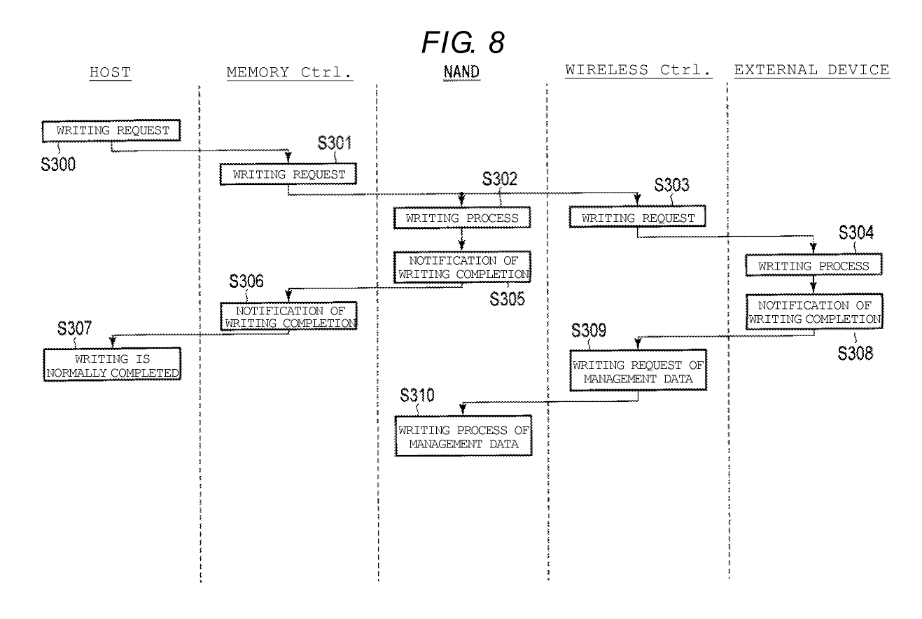

First, a write operation of the memory system 10 will be described. FIG. 8 is a flowchart illustrating the write operation of the memory system 10. In the flowchart of FIG. 8, the communication terminal 43 and/or the external storage device 44 is represented as the external device.

The host device 30 issues a writing request to the memory system 10 (step S300). The writing request includes a command, an address, and data. Subsequently, the memory controller 12 issues the writing request to the NAND type flash memory 13 and the wireless controller 41 in response to the writing request from the host device 30 (step S301).

The NAND type flash memory 13 performs the writing process in response to the writing request from the memory controller 12 (step S302). Furthermore, the wireless controller 41 issues the writing request to the external device through the wireless circuit 42 in response to the writing request from the memory controller 12 (step S303).

The external device performs the writing process in response to the writing request from the wireless controller 41 (step S304). The data written in the external device is the same as the data written in the NAND type flash memory 13. Moreover, since the data is written to the external device using the wireless communication, the writing process of the external device takes time compared to the writing process of the NAND type flash memory 13.

Subsequently, the NAND type flash memory 13 transmits notification of writing completion to the memory controller 12 after the writing process is completed (step S305). Subsequently, the memory controller 12 transmits the notification of the writing completion to the host device 30 (step S306). The host device 30 confirms that the writing is normally completed by receiving the notification of the writing completion from the memory controller 12 (step S307).

Subsequently, the external device transmits the notification of the writing completion to the wireless controller 41 after the writing process is completed (step S308). Subsequently, the wireless controller 41 issues the writing request of the management data including the address (data range) of the data written to the external device to the NAND type flash memory 13 (step S309). Subsequently, the NAND type flash memory 13 performs the writing process of the management data (step S310).

The write data transmitted from the host device 30 is stored in the NAND type flash memory 13 by the write operation described above, and the same write data is stored in the communication terminal 43 and/or the external storage device 44. Furthermore, the address for specifying the write data is stored in the NAND type flash memory 13 as the management data.

[2-2] Read Operation

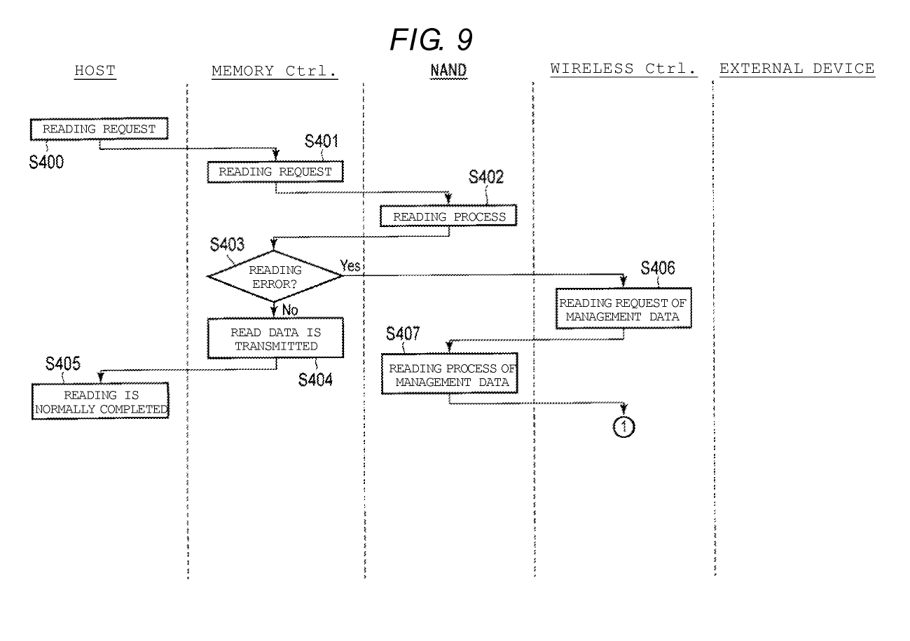

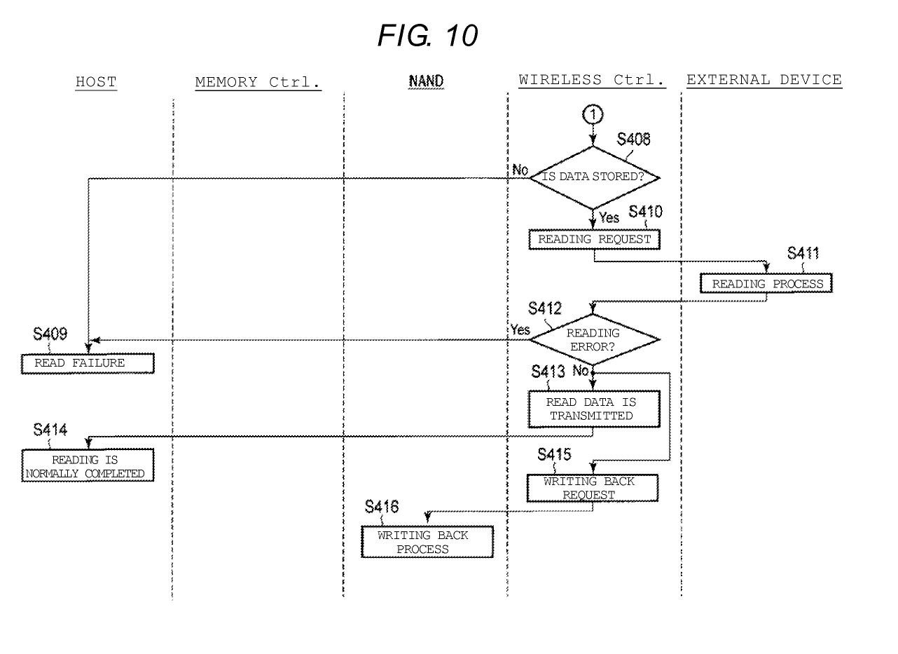

Next, a read operation of the memory system 10 will be described. FIGS. 9 and 10 are flowcharts illustrating the read operation of the memory system 10.

The host device 30 issues a reading request to the memory system 10 (step S400). The reading request includes the command and the address. Subsequently, the memory controller 12 issues the reading request to the NAND type flash memory 13 in response to the reading request from the host device 30 (step S401).

The NAND type flash memory 13 performs a reading process in response to the reading request from the memory controller (step S402). Subsequently, the ECC circuit 40 performs error correction with respect to read data from the memory controller 12. A result of the error correction is transmitted to the memory controller 12. The memory controller 12 determines whether or not a reading error occurs (step S403). The definition of the reading error may be appropriately set depending on the specification of the memory system 10, it may be determined as the reading error if the number of error bits that cannot be corrected exists one or more bits, and it may be determined as the reading error if the number of error bits that cannot be corrected exceeds the number of allowable bits.

In step S403, if there is no reading error, the memory controller 12 transmits the read data to the host device 30 (step S404). The host device 30 recognizes that the reading is normally completed by receiving the read data from the memory controller 12 (step S405).

Meanwhile, in step S403, if there is the reading error, the wireless controller 41 issues the reading request of the management data to the NAND type flash memory 13 (step S406). Subsequently, the NAND type flash memory 13 performs the reading process of the management data (step S407).

Subsequently, the wireless controller 41 determines whether or not data to be read is stored in the external device using the management data read from the NAND type flash memory 13 (step S408). In step S408, if the data to be read is not stored in the external device, it is considered a read failure (step S409).

In step S408, if the data to be read is stored in the external device, the wireless controller 41 issues the reading request to the external device (step S410). The external device performs the reading process in response to the reading request from the wireless controller 41 (step S411). Subsequently, the ECC circuit 40 performs the error correction with respect to the read data from the external device. A result of the error correction is transmitted to the wireless controller 41. The wireless controller 41 determines whether or not the reading error occurs (step S412). In step S412, if there is reading error, it is considered a read failure (step S409).

Meanwhile, in step S412, if there is no reading error, the wireless controller 41 transmits the read data from the external device to the host device 30 (step S413). The host device 30 recognizes that the reading is normally completed by receiving the read data from the wireless controller 41 (step S414).

Furthermore, the wireless controller 41 issues a writing back request to the NAND type flash memory 13 to write back the read data from the external device to the NAND type flash memory 13 (step S415). The writing back request includes the command, the address and the read data from external device. The NAND type flash memory 13 performs a writing back process in response to the writing back request from the wireless controller 41 (step S416). Data that is originally the reading error in the reading process of the NAND type flash memory 13 may be rescued by the writing back process.

[2-3] Another Example of Write Operation

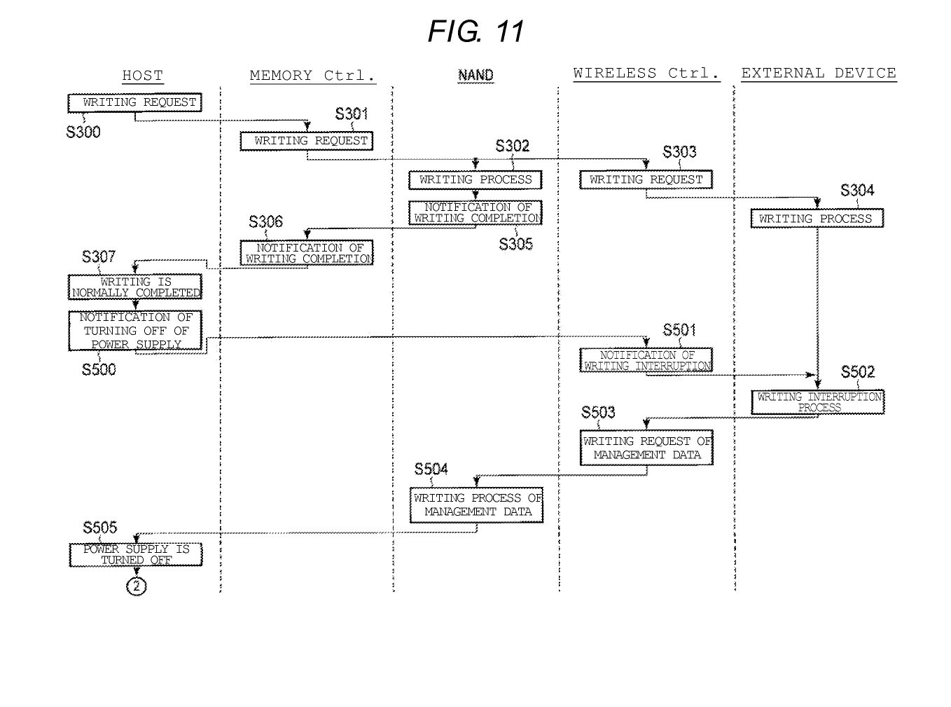

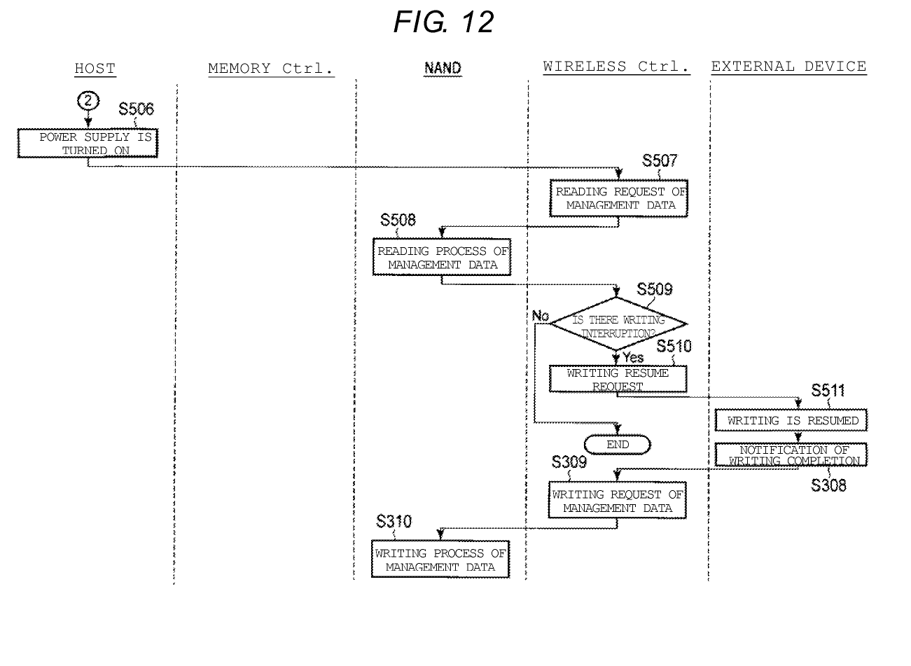

Next, another example of the write operation will be described. Here, a write operation in a case where a power supply of a memory system 10 is turned off in the middle of the write operation will be described. FIGS. 11 and 12 are flowcharts illustrating the write operation of the memory system 10 according to this other example. Steps S300 to S307 of FIG. 11 are the same as those of FIG. 8.

Subsequently, a host device 30 transmits notification of turning off of power supply to the memory system 10 to inform that the power supply of the memory system 10 is turned off (step S500). A wireless controller 41 transmits notification of writing interruption to the external device to interrupt the writing process in response to the notification of turning off of power supply from the host device 30 (step S501).

The external device performs a writing interruption process in response to the notification of writing interruption from the wireless controller 41 (step S502). Specifically, the external device interrupts a current writing process and transmits the address of the data of the write data in this time, in which the writing has been completed already, to the wireless controller 41.

Subsequently, the wireless controller 41 transmits the writing request to the NAND type flash memory 13 (step S503). The writing request writes the management data including the address transmitted from the external device and flag indicating presence or absence of the writing interruption to the NAND type flash memory 13. Subsequently, the NAND type flash memory 13 performs the writing process of the management data (step S504). Thereafter, the power supply of the memory system 10 is turned off (step S505).

Subsequently, the host device 30 turns on the power supply of the memory system 10 (step S506). Subsequently, the wireless controller 41 issues the reading request of the management data to the NAND type flash memory 13 (step S507). Subsequently, the NAND type flash memory 13 performs the reading process of management data (step S508).

Subsequently, the wireless controller 41 determines whether or not the writing process of the external device is interrupted using the management data read from the NAND type flash memory 13 (step S509). In step S509, if there is no writing interruption, the wireless controller 41 completes the process. Meanwhile, in step S509, if there is the writing interruption, the wireless controller 41 transmits a writing resume request to the external device. The writing resume request includes the command data in which the writing is not completed and the address thereof. The data in which the writing is not completed is read by the wireless controller 41 from the NAND type flash memory 13.

Subsequently, the external device resumes the writing in response to the writing resume request from the wireless controller 41 (step S511). Thereafter, steps S308 to S310 are the same as those of FIG. 8.

Even if the writing process is interrupted in the external device, thereafter, if the power supply of the memory system 10 is turned on, it is possible to store the write data in its entirety in the external device by the write operation described above. The write operation of the embodiment is specifically effective in a case where the wireless communication speed is slow.

[3] Effects

As described above, in the second embodiment, the memory system 10 includes the wireless circuit 42 that performs the wireless communication with the external device (including the communication terminal 43 and the external storage device 44). Then, the wireless controller 41 writes the same data as the data that is written in the NAND type flash memory 13 to the external device.

Thus, according to the second embodiment, if the reading error occurs in the read operation from the NAND type flash memory 13, it is possible to transmit the data stored in the external device to the host device 30. Thus, it is possible to improve data reliability of the memory system 10 as viewed from the host device 30.

Generally, in order to improve the data reliability, it is necessary to enhance an error correction capability of the ECC circuit, but a circuit area of the ECC circuit having a high error correction capability is increased and a time for the error correction is also long. Furthermore, the data stored in the memory system may be destroyed by a physical stress (heat, impact, and the like).

In contrast, in the embodiment, since the data stored in the external device maybe used, it is not necessary to rely solely on the error correction capability of the ECC circuit and it is possible to lower the error correction capability of the ECC circuit. Furthermore, even if the memory system 10 is used in an environment in which the physical stress is great, it is possible to improve the data reliability of the memory system 10.

Furthermore, if the power supply of the memory system 10 is turned off while the data is written to the external device, the notification of writing interruption is transmitted to the external device and the address of the data that has been written already is written to the NAND type flash memory 13 as the management data. Then, if the power supply of the memory system 10 is turned on again, the writing is resumed only in an unwritten data portion. Thus, it is possible to accurately store the data in the external device.

Moreover, the thermoelectric device 17 and the power control according to the first embodiment may be applied to those of the second embodiment.

Moreover, for example, the configuration of the memory cell array is described in “THREE DIMENSIONAL STACKED NONVOLATILE SEMICONDUCTOR MEMORY”, U.S. patent application Ser. No. 12/407,403 filed on Mar. 19, 2009. Furthermore, the configuration is described in “THREE DIMENSIONAL STACKED NONVOLATILE SEMICONDUCTOR MEMORY”, U.S. patent application Ser. No. 12/406,524 filed on Mar. 18, 2009, “NONVOLATILE SEMICONDUCTOR STORAGE DEVICE AND MANUFACTURING METHOD THE SAME”, U.S. patent application Ser. No. 12/679,991 filed on Mar. 25, 2010, and “SEMICONDUCTOR MEMORY AND MANUFACTURING METHOD THE SAME”, U.S. patent application Ser. No. 12/532,030 filed on Mar. 23, 2009. Those patent applications are incorporated by reference herein in their entirety.

In each embodiment, (1) in the read operation, the voltage applied to the word line selected in the read operation of an A level is, for example, between 0 V to 0.55 V. The configuration is not limited to the embodiment and the voltage may be one of between 0.1 V to 0.24 V, 0.21 V to 0.31 V, 0.31 V to 0.4 V, 0.4 V to 0.5 V, and 0.5 V to 0.55 V.

The voltage applied to the word line selected in the read operation of a B level is, for example, between 1.5 V to 2.3 V. The configuration is not limited to the embodiment and the voltage may be one of between 1.65 V to 1.8 V, 1.8 V to 1.95 V, 1.95 V to 2.1 V, and 2.1 V to 2.3 V.

The voltage applied to the word line selected in the read operation of a C level is, for example, between 3.0 V to 4.0 V. The configuration is not limited to the embodiment and the voltage may be one of between 3.0 V to 3.2 V, 3.2 V to 3.4 V, 3.4 V to 3.5 V, 3.5 V to 3.6 V, and 3.6 V to 4.0 V.

The time (tR) of the read operation may be, for example, between 25 μs to 38 μs, 38 μs to 70 μs, and 70 μs to 80 μs.

(2) The writing operation includes the program operation and the verify operation as described above. In the write operation, the voltage initially applied to the word line selected in the program operation is, for example, between 13.7 V to 14.3 V. The configuration is not limited to the embodiment and the voltage may be one of between 13.7 V to 14.0 V and 14.0 V to 14.6 V.

The voltage initially applied to the word line selected when writing the odd-numbered word lines and the voltage initially applied to the word line selected when writing the even-numbered word lines may be changed.

When the program operation is performed in an Incremental Step Pulse Program (ISPP) type, as a voltage of step-up, for example, approximately 0.5 V is exemplified.

The voltage applied to a non-selected word line may be, for example, between 6.0 V to 7.3 V. The configuration is not limited to the example and may be, for example, between 7.3 V to 8.4 V, or may be 6.0 V or less.

The pass voltage to be applied may be changed whether the non-selected word line is the word line of the odd-numbered word line or the word line of the even-numbered word line.

The time (tProg) of the write operation may be, between 1,700 μs to 1,800 μs, 1,800 μs to 1,900 μs, and 1,900 μs to 2,000 μs.

(3) In the erasing operation, the voltage initially applied to the well which is formed on the upper portion of the semiconductor substrate and in which the memory cell is disposed on the upper portion thereof is, for example, between 12 V to 13.6 V. The configuration is not limited to the example and the voltage may be one of, for example, between 13.6 V to 14.8 V, 14.8 V to 19.0 V, 19.0 V to 19.8 V, and 19.8 V to 21V.

The time (tErase) of the erasing operation may be, for example, between 3,000 μs to 4,000 μs, 4,000 μs to 5,000 μs, and 4,000 μs to 9,000 μs.

(4) The structure of the memory cell has a charge storage layer that is disposed on the semiconductor substrate (silicon substrate) through a tunnel insulation film having a film thickness of 4 nm to 10 nm. The charge storage layer may be a stacked structure of an insulation film of SiN or SiON, and the like having a film thickness of 2 nm to 3 nm and polysilicon having a film thickness of 3 nm to 8 nm. Furthermore, a metal such as Ru may be added to the polysilicon. An insulation film is provided on the charge storage layer. For example, the insulation film has a silicon oxide film having a film thickness of 4 nm to 10 nm interposed between a lower layer High-k film having a film thickness of 3 nm to 10 nm and an upper layer High-k film having a film thickness of 3 nm to 10 nm. As the High-k film, HfO and the like are exemplified. Furthermore, the film thickness of the silicon oxide film may be thicker than the film thickness of the High-k film. A control electrode having a film thickness of 30 nm to 70 nm is formed on the insulation film through a material for work function adjustment having a film thickness of 3 nm to 10 nm. Here, a material for the work function adjustment is a metal oxide film such as TaO, a metal nitride film such as TaN. As the control electrode, W and the like may be used.

Furthermore, an air gap may be formed between the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a nonvolatile memory;
a thermoelectric device configured to generate power from heat;
a main power supply for the nonvolatile memory;
a backup power supply for the nonvolatile memory, the backup power supply including a capacitor; and
a power supply controller configured to supply the power generated by the thermoelectric device to the capacitor to charge the capacitor.

2. The system according to claim 1,
wherein the power supply controller is configured to supply the power generated by the thermoelectric device to the nonvolatile memory after charging of the capacitor is completed.

3. The system according to claim 1, further comprising:
a cooling fan,
wherein the power supply controller is configured to supply the power generated by the thermoelectric device to the cooling fan when an internal temperature exceeds a threshold.

4. The system according to claim 1, further comprising:
an interface circuit by which commands from a host is received.

5. The system according to claim 4, further comprising:
a memory controller for the nonvolatile memory.

6. The system according to claim 5, wherein the thermoelectric device is in contact with the memory controller.

7. The system according to claim 1, further comprising:
a wireless circuit configured to communicate wirelessly with an external storage device;
a memory controller configured to store write data sent from a host to the nonvolatile memory and to transmit the write data to the external storage device through the wireless circuit for storage therein; and
an ECC circuit configured to correct an error in read data read from the nonvolatile memory,
wherein the wireless circuit is configured to receive a copy of the read data stored in the external device if the error in the read data read from the nonvolatile memory cannot be corrected.

8. The system according to claim 7,
wherein management data including an address of the write data stored in the external storage device is written in the nonvolatile memory.

9. The system according to claim 8,
wherein the wireless circuit is configured to determine whether the read data is stored in the external device based on the management data.

10. The system according to claim 7,
wherein the management data includes an indication that storing of a copy of the write data in the external storage device has been interrupted, and the wireless circuit is configured to request the external storage device to resume the storing of the copy of the write data therein.

11. A method of managing power in a memory system that includes a nonvolatile memory, a thermoelectric device, amain power supply for the nonvolatile memory, and a backup power supply, including a capacitor, for the nonvolatile memory, said method comprising:
generating power from heat using the thermoelectric device; and
supplying the power generated by the thermoelectric device to the capacitor to charge the capacitor.

12. The method of claim 11, further comprising:
supplying the power generated by the thermoelectric device to other components of the memory system after charging of the capacitor has completed.

13. The method of claim 12, wherein the memory system includes a cooling fan, and after charging of the capacitor has completed, the power generated by the thermoelectric device is supplied to the cooling fan when an internal temperature exceeds a threshold.

14. The method of claim 13, wherein, after charging of the capacitor has completed, the power generated by the thermoelectric device is supplied to the nonvolatile memory when the internal temperature is below the threshold.

15. The method of claim 11, further comprising:
receiving write, read, and erase commands from a host; and
controlling the nonvolatile memory to perform write, read, and erase operations in accordance with the commands from the host.

16. The method of claim 11, further comprising:
receiving a write command from a host;
controlling the nonvolatile memory to perform a write operation in accordance with the write command; and
wirelessly transmitting the write data to an external storage device for storage therein.

17. The method of claim 16, further comprising:
receiving a read command from the host;
controlling the nonvolatile memory to perform a read operation in accordance with the read command; and
correcting an error in read data returned from the nonvolatile memory.

18. The method of claim 17, further comprising:
receiving a copy of the read data stored in the external device if the error in the read data returned from the nonvolatile memory cannot be corrected.

19. The method of claim 16,
wherein management data including address of the write data stored in the external storage device is written in the nonvolatile memory.

20. The method of claim 19, wherein the management data includes an indication that storing of a copy of the write data in the external storage device has been interrupted, and further comprising:
requesting the external storage device to resume the storing of the copy of the write data therein.
